(19) United States
(12) Patent Application Publication
(10) Pub. No.: US 2005/0136344 A1
(43) Pub. Date: Jun. 23, 2005

(54) Donor film for laser induced thermal imaging method and organic electroluminescence display device fabricated using the film

(76) Inventors: Tae-Min Kang, Suwon-si (KR); Myung-Won Song, Suwon-si (KR); Jae-Ho Lee, Suwon-si (KR); Seong-Taek Lee, Suwon-si (KR)

Correspondence Address: Robert E. Bushnell;Suite 300, 1522 K Street, N.W., Washington, DC, 20005, US

(21) Appl. No.: 10/968,918

(22) Filed: Oct. 21, 2004

(30) Foreign Application Priority Data
Dec. 22, 2003 (KR) 2003-94945

(51) Int. Cl. G03C 3/00; B41M 5/24

(52) U.S. Cl. 430/18

(57) ABSTRACT

A donor film for laser induced thermal imaging method having a base film, a light-to-heat conversion layer formed on the base film, a reflection layer or a metal layer formed on the light-to-heat conversion layer, and a transfer layer formed on the reflection layer and formed of an organic material. The donor film is capable of reducing an edge open defect and increasing The amount of energy absorbed into the light-to-heat conversion layer by forming either the reflection layer or the metal layer between the light-to-heat conversion layer and the transfer layer, preventing damage of the substrate by not transmitting a laser beam to the substrate and prevents deterioration of the transfer layer by preventing gas generated from the light-to-heat conversion layer by heat from penetrating into the transfer layer and dissipating heat transferred to the transfer layer well into the transfer layer.

### CLAIM OF PRIORITY

This application makes reference to, incorporates the same herein, and claims all benefits accruing under 35 U.S.C. §119 from an application for DONOR FILM FOR LASER INDUCED THEREMAL IMAGING METHOD AND ORGANIC ELECTROLUMINESCENCE DISPLAY DEVICE FABRICATED USING THE FILM earlier filed in the Korean Intellectual Property Office on 22 Dec. 2003 and thereduly assigned Serial No. 2003-94945.

### BACKGROUND OF THE INVENTION

1. Field of the Invention

The present invention relates to a donor film for laser induced thermal imaging method and an organic electroluminescence display device fabricated using the film, more particularly, to a donor film used for forming an organic layer for an organic electroluminescence display device and an organic electroluminescence display device prepared by using the donor film.

2. Description of Related Art

Generally, an organic electroluminescence display device is formed of various layers including an anode and a cathode, a hole injection layer, a hole transport layer, an emitting layer, an electron transport layer and an electron injection layer. The organic electroluminescence display device is divided into a polymeric organic electroluminescence display device and a small molecular organic electroluminescence display device according to materials used in the organic electroluminescence display device. The respective layers are introduced into the organic electroluminescence display device by vacuum deposition in case of the small molecular organic electroluminescence display device and by a spin coating process in case of the polymeric organic electroluminescence display device.

The single color polymeric organic electroluminescence display device is simply fabricated using a spin coating process, but the polymeric organic electroluminescence display device has problems because emission efficiency and life cycle are diminished although driving voltage is lower compared to the small molecular organic electroluminescence display device. Furthermore, when fabricating a full color organic electroluminescence display device in which red, green and blue high molecules are patterned, the polymeric organic electroluminescence display device has problems that emission characteristics including emission efficiency and life cycle are deteriorated when using inkjet technology or a laser induced thermal imaging method.

Particularly, when patterning a polymeric organic electroluminescence display device using the laser induced thermal imaging method, a single material is generally not transferred on the polymeric organic electroluminescence display device.

A method for forming patterns of a polymeric organic electroluminescence display device by the laser induced thermal imaging method is disclosed in Korean Patent No. 1998-51844 and U.S. Pat. No. 5,998,085 entitled Process for preparing high resolution emissive arrays and corresponding articles by Isberg et al., issued on Dec. 7, 1999, U.S. Pat. No. 6,214,520 entitled Thermal transfer element for forming multilayer devices by Wolk et al., issued on Apr. 10, 2001, and U.S. Pat. No. 6,114,088 entitled Thermal transfer element for forming multilayer devices by Wolk et al., issued on Sep. 5, 2000.

In order to apply the laser induced thermal imaging method, at least a light source, a transfer film and a substrate are required, and light coming out of the light source is absorbed into a light absorption layer of the transfer film and converted into a thermal energy so that a transfer layer forming material of the transfer film is transferred onto the substrate by the thermal energy, thereby forming a desired image as disclosed in U.S. Pat. No. 5,220,348 entitled Electronic drive circuit for multi-laser thermal printer by D'Aurelio, issued on Jun. 15, 1993, U.S. Pat. No. 5,256,506 entitled Ablation-transfer imaging/recording by Ellis et al., issued on Oct. 26, 1993, U.S. Pat. No. 5,278,023 entitled Propellant-containing thermal transfer donor elements by Bills et al., issued on Jan. 11, 1994, and U.S. Pat. No. 5,308,737 entitled Laser propulsion transfer using black metal coated substrates by Bills et al., issued on May 3, 1994.

The laser induced thermal imaging method is used in fabrication of a color filter for a liquid crystal display device and used to form patterns of emitting materials as disclosed in U.S. Pat. No. 5,998,085 entitled Process for preparing high resolution emissive arrays and corresponding articles by Isberg et al., issued on Dec. 7, 1999.

U.S. Pat. No. 5,937,272 entitled Patterned organic layers in a full-color organic electroluminescent display array on a thin film transistor array substrate by Tang, issued on Aug. 10, 1999 relates to a method for forming a high quality patterned organic layer in a full color organic electroluminescence display device, and a donor supporting body obtained by coating an organic electroluminescence substance with a transferable coating material is used in the method. The donor supporting body is heated so that the organic electroluminescence substance is transferred onto a recess surface part of the substrate for forming a colorized organic electroluminescence medium positioned in a targeted lower pixel, wherein the organic electroluminescence substance is transferred onto the pixel by applying heat or light to a donor film.

It is disclosed in U.S. Pat. No. 5,688,551 entitled Method of forming an organic electroluminescent display panel by Littman et al., issued on Nov. 18, 1997 that sub-pixels are formed on each pixel region by transferring organic electroluminescence substance from a donor sheet to a receiver sheet, wherein the sub-pixels are formed by transferring an organic electroluminescence substance having sublimation property from the donor sheet to the receiver sheet at low temperature of about 400° C. or less in the transferring process.

However, the organic electroluminescence substance is not completely transferred from the donor sheet to the receiver sheet when using the laser induced thermal imaging method because the stepped surface level exists on an edge part of a pixel region of the organic electroluminescence display device by a pixel defining layer. This is called as an edge open defect or a non-transfer defect. The edge open defect is generated due to a large radius of the curvature made in a layer such as the light-to-heat conversion layer or a buffer layer which is expanded by receiving laser energy. That is, the edge open defect is generated since an expanded part has a large thickness.

The edge open defect causes problems by reducing the emission efficiency and life time of the organic electroluminescence display device are deteriorated, and also reducing.

### SUMMARY OF THE INVENTION

It is therefore an object of the present invention to provide an improved donor film for laser induced thermal imaging.

It is also an object of the present invention to provide a donor film for laser induced thermal imaging capable of preventing a non-transfer defect during fabrication of an organic electroluminescence display device.

It is further an object of the present invention to provide a donor film capable of preventing thermal damage of the transfer layer.

In order to achieve the foregoing and other objects, the present invention provides a donor film for laser induced thermal imaging. The donor film includes a base film, a light-to-heat conversion layer formed on the base film, a metal layer formed on the light-to-heat conversion layer, a buffer layer formed on the metal layer, and a transfer layer formed on the buffer layer and formed of an organic material.

Furthermore, the present invention provides a donor film for laser induced thermal imaging, with a base film, a light-to-heat conversion layer formed on the base film, a transfer layer, and a reflection layer formed between the light-to-heat conversion layer and the transfer layer to reflect an irradiated laser to the light-to-heat conversion layer and to prevent gas formed from the light-to-heat conversion layer from infiltrating into the transfer layer.

### BRIEF DESCRIPTION OF THE DRAWINGS

A more complete appreciation of the present invention, and many of the above and other features and advantages of the present invention, will be readily apparent as the same becomes better understood by reference to the following detailed description when considered in conjunction with the accompanying drawings in which like reference symbols indicate the same or similar components, wherein:

FIG. 1 is a cross sectional view showing a structure of a conventional full color organic electroluminescence display device;

FIG. 2 is a cross sectional view showing a structure of a conventional donor film for a laser induced thermal imaging method;

FIG. 3 is a drawing showing a transfer model in case of using a conventional donor film;

FIG. 4 is a graph showing a relation between a stepped surface level generated by the pixel defining layer and the edge open defect as a relation between the size of the stepped surface level (i.e., the step height) and the radius of the curvature of an expansion part of a donor film;

FIG. 5 is a drawing illustrating a transfer mechanism when transfer-patterning an organic emitting film used in an organic electroluminescence display device by using a laser;

FIG. 6 is a drawing showing a structure of a donor film for a laser induced thermal imaging method according to a first preferred embodiment of the present invention;

FIG. 7 is a graph showing energy transfer and the degree of energy absorption at respective positions of a light-to-heat conversion layer according to laser irradiation when the light-to-heat conversion layer is laid to a relatively large thickness of 4 μm when using a conventional donor film;

FIG. 8 is a graph showing energy transfer and the degree of energy absorption at respective positions of the light-to-heat conversion layer according to laser irradiation when forming the light-to-heat conversion layer of a donor film as a preferred embodiment of the present invention to a thickness of 0.5 μm and using a metal layer;

FIG. 9 is a drawing showing a structure of a donor film for a laser induced thermal imaging method according to a second preferred embodiment of the present invention; and

FIG. 10 is a drawing describing a method for laser induced thermal imaging using a donor film as a present invention.

### DETAILED DESCRIPTION OF THE INVENTION

The present invention will now be described in detail in connection with preferred embodiments with reference to the accompanying drawings. For reference, like reference characters designate corresponding parts throughout several views. In the drawings and the specification, when a layer is shown as placed on another layer or on a substrate in order to indicate that a layer is either directly formed upon the other layer or on the substrate or, alternatively, that a layer is formed on a third layer, which, in turn, rests upon either the other layer or the substrate. Like numbers refer to like elements throughout the specification.

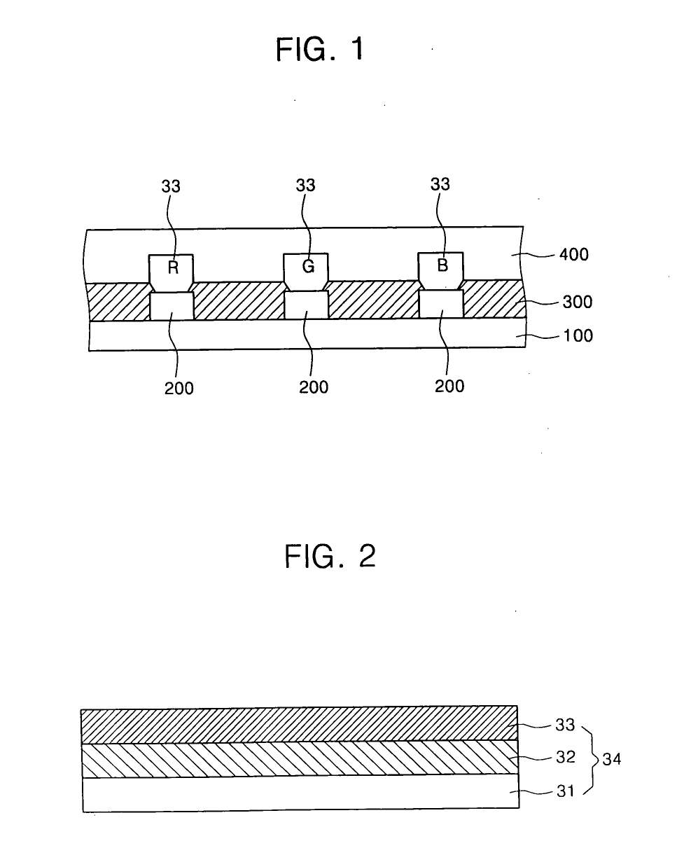

FIG. 1 is a cross sectional view for showing a structure of a conventional full color organic electroluminescence display device.

Referring to FIG. 1, a first electrode 200 is patterned on an insulating substrate 100. The first electrode 200 is formed of a transparent electrode when the full color organic electroluminescence display device is a bottom emitting type. The first electrode 200 is formed of a conductive metal with a reflection film when the full color organic electroluminescence display device is a top emitting type.

A pixel defining layer (PDL) 300 is formed of an insulating material on an upper part of the first electrode 200 to define a pixel region and to insulate an emitting layer from another emitting layer.

An organic film layer 33 made of an organic emitting layer (R, G and B) is formed on the pixel region defined by the pixel defining layer (PDL) 300, and the organic film layer 33 may include a hole injection layer, a hole transport layer, a hole blocking layer, an electron transport layer and/or an electron injection layer in addition to the organic emitting layer. Either a polymeric substance or a small molecular substance can be used as the organic emitting layer.

A second electrode 400 is formed on the organic film layer 33. The second electrode 400 is formed of a conductive metal layer with the reflection film if the first electrode 200 is a transparent electrode, and the second electrode 400 is formed of a transparent electrode if the first electrode 200 is a conductive metal layer with the reflection film. An organic electroluminescence display device is completed by sealing the organic electroluminescence display device after forming the second electrode 400.

However, as illustrated in FIG. 2, a conventional donor film 34 for laser induced thermal imaging has a base film 31, the light-to-heat conversion layer 32 and transfer layer 33 and further has a buffer layer (not shown in FIG. 2) in case of forming an emitting layer using a conventional laser induced thermal imaging.

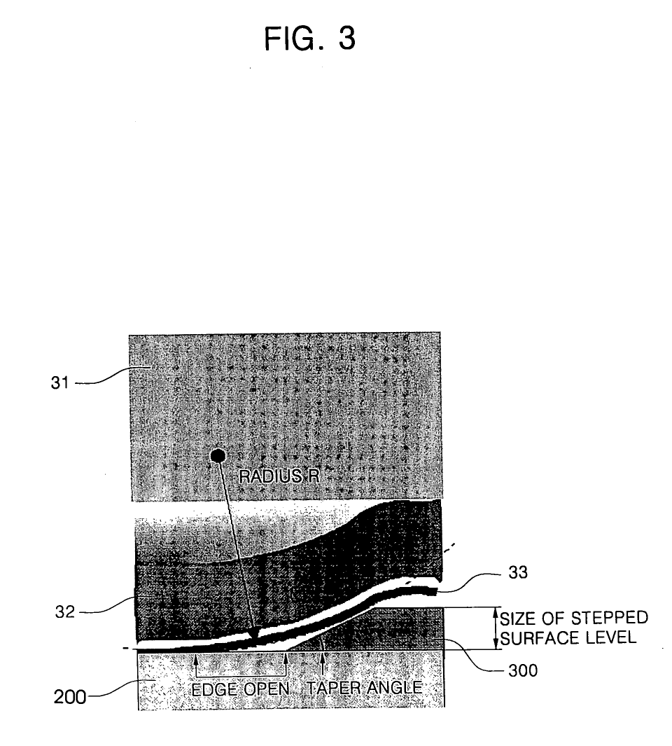

FIG. 3 relates to a transfer model when using a conventional donor film. The transfer layer 33 is separated from a donor film 34 and transferred to a substrate of an organic electroluminescence display device as the transfer layer 33 is being expanded according to expansion of a light-to-heat conversion layer 32 during laser irradiation as illustrated in FIG. 3.

However, when forming the emitting layer using the laser induced thermal imaging method, the transfer layer 33 is not completely transferred because a stepped surface level exists on an edge part of the pixel region of the organic electroluminescence display device. This is called as an edge open defect or a non-transfer defect. The edge open defect is generated due to a large radius of the curvature made in a layer such as the light-to-heat conversion layer 32 or a buffer layer (not illustrated in FIG. 3) which is expanded by receiving laser energy. That is, the thick expanded part causes the edge open defect.

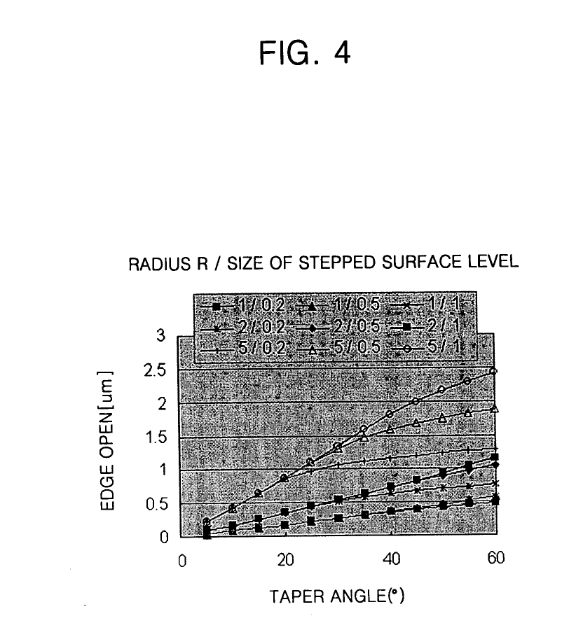

FIG. 4 is a graph showing a relation between a stepped surface level generated by the pixel defining layer and the edge open defect as a relation between the size of the stepped surface level and the radius of the curvature of an expansion part of the donor film.

As shown in FIG. 4, the larger size of the stepped surface level, the more edge open defects. Also, when the sizes of the stepped surface levels are equal, the larger radius of the curvature causes the more edge open defects. The edge open defect causes the deterioration of emission efficiency, life time and color characteristics of an organic electroluminescence display device.

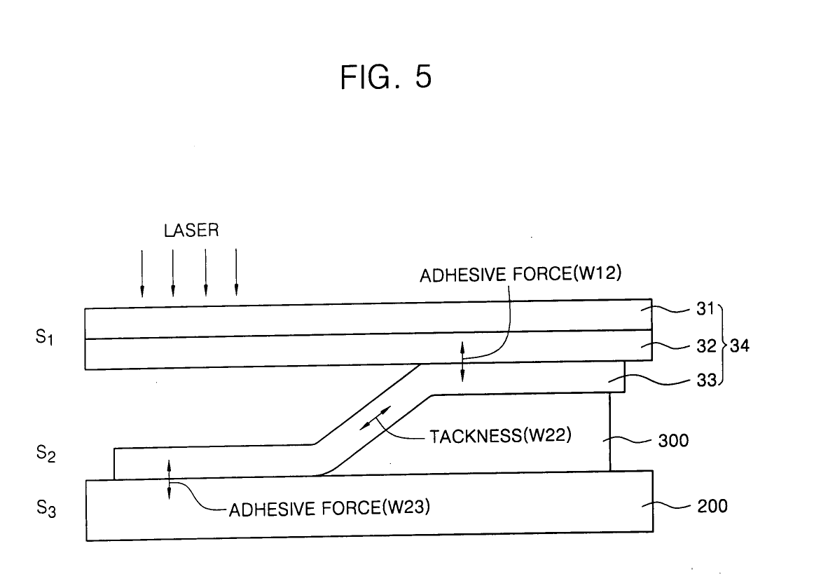

FIG. 5 is a drawing illustrating a transfer mechanism when transfer-patterning an organic emitting film used in an organic electroluminescence display device by using a laser according to the present invention.

In a mechanism for transfer-patterning an organic film using a conventional laser, when a laser beam is irradiated on an organic film S2, the irradiated part of the organic film S2 is detached from a substrate S1. However, the part of the organic film S2 which is not irradiated is not detached from the substrate S1 as illustrated in FIG. 5.

Factors for affecting transfer characteristics are first adhesive force W₁₂ between the substrate S1 and the film S2, tackiness W₂₂ of the film, and second adhesive force W₂₃ between the film S2 and the substrate S3.

The first and second adhesive forces and tackiness are represented as the following expressions using surface tensions γ₁, γ₂ and γ₃ and interfacial tensions γ₁₂ and γ₂₃ of respective layers.
W₁₂=γ₁+γ₂−γ₃
W₂₂=2_{γ2}
W₂₃=γ₂+γ₃−γ₂₃

In order to improve laser transfer characteristics, the tackiness (W₂₂) of the film should be less than adhesive forces (W₁₂, W₂₃) between the respective substrates and the film.

Generally, an organic material is used in an organic electroluminescence display device as a material for forming respective layers of the organic electroluminescence display device. If a small molecular material is used as the organic material, the first and second adhesive forces are greater than the tackiness so that fine patterns of the emitting layer can be formed and the possibility of misalighment can be decreased by transferring an emitting material from a donor film 34 to the organic electroluminescence display device.

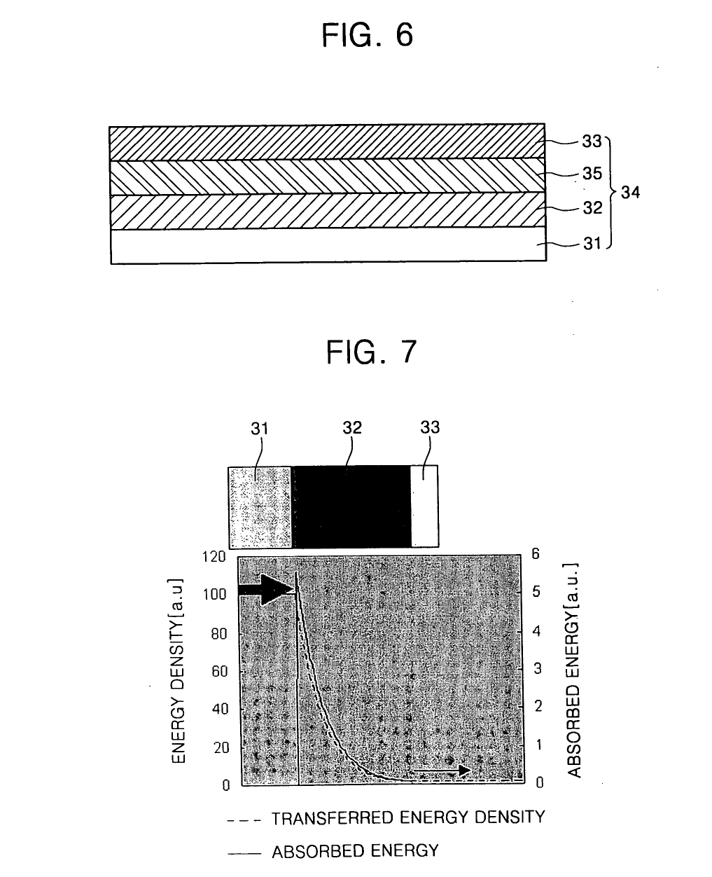

FIG. 6 is a drawing showing a structure of a donor film for small molecular laser induced thermal imaging according to a first preferred embodiment of the present invention.

Referring to FIG. 6, the donor film 34 has a structure in which a base film 31, a light-to-heat conversion layer 32 formed on an upper part of the base film 31, a metal layer 35 formed on an upper part of the light-to-heat conversion layer 32 over the base film 31, and a transfer layer 33 formed over an upper part of the metal layer 35. The transfer layer 33 is formed of an organic material are laid.

The structure of the donor film of FIG. 6 can be changed according to its applications. For example, the donor film further comprises a gas forming layer (not illustrated in FIG. 6) on either an upper part or a lower part of the light-to-heat conversion layer, and a buffer layer (not illustrated in FIG. 6) formed between the metal layer 35 and the transfer layer 33 to improve sensitivity of the film.

The base film 31 is formed of transparent polymers including polyester such as polyethylene terephthalate, polyacryl, polyepoxy, polyethylene, and polystyrene. A composite multi-component substrate can be also used as the base film 31. Particularly, a polyethylene terephthalate film is mainly used as the transparent polymer. It is preferable that the base film has a thickness of 10 to 500 μm. The base film functions as a supporting substrate.

The light-to-heat conversion layer 32 is formed of a light absorbing material having a property of absorbing light in the infrared ray-visible ray range. The light-to-heat conversion layer 32 can be an organic film containing laser-light absorbing material, or a metallic compound such as metal, metal oxide, metal sulfide and a composite layer thereof.

The organic film can be formed of polymer to which carbon black, graphite or infrared dye is added as a film having the above characteristics. The metal, metal oxide and metal sulfide have an optical density of 0.1 to 4.0, and preferably include aluminum (Al), silver (Ag), chromium (Cr), tin (Sn), nickel (Ni), titanium (Ti), cobalt (Co), zinc (Zn), gold (Au), copper (Cu), tungsten (W), molybdenum (Mo), lead (Pb), oxide thereof, or mixture thereof. More preferably, the metal, metal oxide and metal sulfide include aluminum (Al), silver (Ag), or oxide thereof.

The organic film formed of polymer to which carbon black, graphite or infrared dye is added can be a polymer bonding resin in which pigment, colorant such as dyes, dispersant, etc. are dispersed. The polymer bonding resin can be meta-acrylate oligomer such as acryl meta-acrylate oligomer, ester meta-acrylate oligomer, epoxy meta-acrylate oligomer and urethane meta-acrylate oligomer, a mixture of the meta-acrylate oligomer and meta-acrylate monomer, or meta-acrylate monomer. It is preferable that the carbon black or graphite has a particle diameter of 0.5 μm or less and an optical density of 0.1 to 4.

On the other hand, if the thickness of the light-to-heat conversion layer 32 is too thin, an energy absorption ratio is lowered so that expansion pressure is lowered due to low light-to-heat conversion energy, and transmission energy is increased so that substrate circuits of an organic electroluminescence display device are damaged.

Furthermore, the edge open defect caused by stepped surface level generated by a pixel defining layer is reduced by maintaining the light-to-heat conversion layer 32 to a certain thickness or less in order to decrease the radius of the curvature during expansion of the light-to-heat conversion layer 32.

On the other hand, if the thickness of the light-to-heat conversion layer 32 is too thick, there is a strong possibility of an edge open defect due to poor close adhesion between the film and the substrate at a part of the stepped surface level generated by a pixel defining layer.

Therefore, the light-to-heat conversion layer 32 is formed to a thickness of 100 to 5,000 Å by vacuum deposition, electron beam deposition or sputtering if the light-to-heat conversion layer 32 is a metal, metal oxide or metal sulfide. The light-to-heat conversion layer 32 is laid to a thickness of 0.1 to 2 μm by a conventional film coating method of extrusion, gravure coating, spin coating or knife coating if the light-to-heat conversion layer 32 is an organic film.

FIG. 7 is a graph showing energy transfer and the degree of energy absorption at respective positions of the light-to-heat conversion layer 32 according to laser irradiation when the light-to-heat conversion layer 32 is laid to a relatively large thickness of 4 μm when using a conventional donor film. Referring to FIG. 7, it is difficult to closely attach the light-to-heat conversion layer to the substrate as a thick layer including most of the light-to-heat conversion layer, the buffer layer and the transfer layer 33 is expanded although energy efficiency is good by absorbing most of the energy at a laser beam incidence part of the light-to-heat conversion layer and absorbing most of the energy while the energy is passing through the light-to-heat conversion layer.

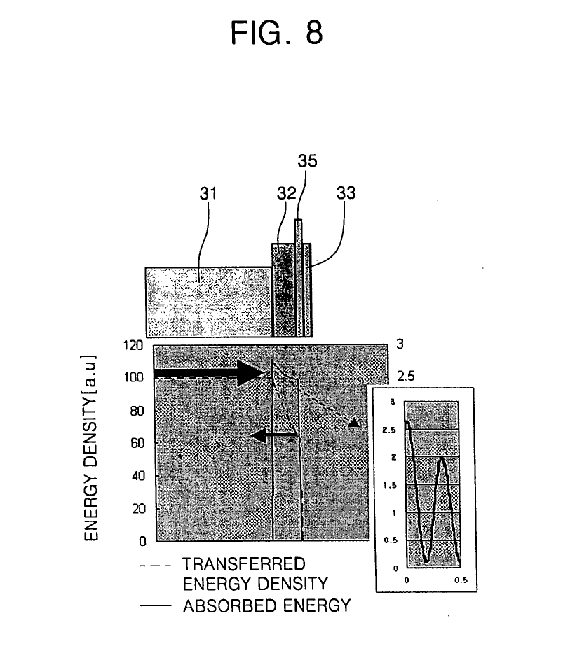

On the contrary, FIG. 8 is a graph showing energy transfer and the degree of energy absorption degree at respective positions of the light-to-heat conversion layer 32 according to laser irradiation when forming the light-to-heat conversion layer 32 of a donor film 34 according to a preferred embodiment of the present invention with a thickness of 0.5 μm and using the metal layer 35. Referring to FIG. 8, energy absorbed into the light-to-heat conversion layer as passing through the light-to-heat conversion layer 32 according to laser irradiation is decreased since the thickness of the light-to-heat conversion layer is thinned. However, since, by using a metal reflection layer, only the small thickness of the buffer layer and the transfer layer needs to be pushed, thereby absorbing the laser light reflected by the metal reflection layer so that energy efficiency is increased, and the energy is further uniformized in the light-to-heat conversion layer so as to uniformly expand the light-to-heat conversion layer as a whole. Therefore, the light-to-heat conversion layer is easily closely adhered to the substrate even by small energy.

Furthermore, the gas forming layer plays a role of providing transfer energy by generating decomposition reaction when light or heat is absorbed into the gas forming layer, thereby emitting nitrogen gas or hydrogen gas. The gas forming layer is formed of a material selected from pentaerythritol tetranitrate (PETN), trinitrotoluene (TNT), etc. Since the gas forming layer should receive heat from the light-to-heat conversion layer, the gas forming layer is formed adjacently to either an upper part or a lower part of the light-to-heat conversion layer or mixed with material of the light-to-heat conversion layer to form a single layer.

A metal having a laser beam transmittance of 20% or less is used as a metal layer 35 formed on an upper part of the light-to-heat conversion layer 32 over the base film. Furthermore, the metal layer 35 is laid to a thickness of 1 μm or less by vacuum deposition, electron beam deposition or sputtering. Thickness of the metal layer 35 is formed to such a degree that laser light is hardly transferred onto the substrate of an organic electroluminescence display device. If the metal layer is too thick, the characteristics of the laser induced thermal imaging may be affected because the metal layer is not expanded when the light-to-heat conversion layer is expanded.

The metal layer not only prevents substrate circuits from being damaged, but also prevents gas generated in the light-to-heat conversion layer 32 from infiltrating into the transfer layer 33 since laser energy is not transferred to the substrate of an organic electroluminescence display device due to the metal layer during laser induced thermal imaging. Additionally, the metal layer 35 prevents thermal damage of the transfer layer by using a metal having high thermal conductivity to dissipate heat transferred to the transfer layer 33 from the light-to-heat conversion layer 32.

A buffer layer (not illustrated in FIG. 8) can be further formed on an upper part of the metal layer 35. The buffer layer prevents metal from being diffused into the transfer layer and controls adhesive force of the metal layer with the transfer layer so that characteristics of transfer-patterns are improved. A metal oxide, metal sulfide, nonmetal inorganic compound or organic material can be used as the buffer layer. The metal oxide can be formed by oxidizing the surface of the metal layer or proceeding a separate process after forming a metal layer. The organic material may be formed by coating an inert polymer or depositing small molecules forms the organic material. The thickness of the buffer layer is preferably 0.01 to 2 μm.

The transfer layer 33 is formed of at least one material selected from a polymeric or small molecular organic electroluminescence material, a hole transferable organic material and an electron transferable organic material so that the transfer layer corresponds to characteristics of an organic electroluminescence display device to be fabricated. The transfer layer is preferably coated to a thickness of 100 to 50,000 Å by a conventional coating method including extrusion, gravure coating, spin coating, knife coating, vacuum deposition and CVD (chemical vapor deposition).

As described in the above, the laser is reflected by the metal layer 35 by introducing a metal layer 35 between the light-to-heat conversion layer 32 and the transfer layer 33 so that more energy is transferred to the light-to-heat conversion layer 32.

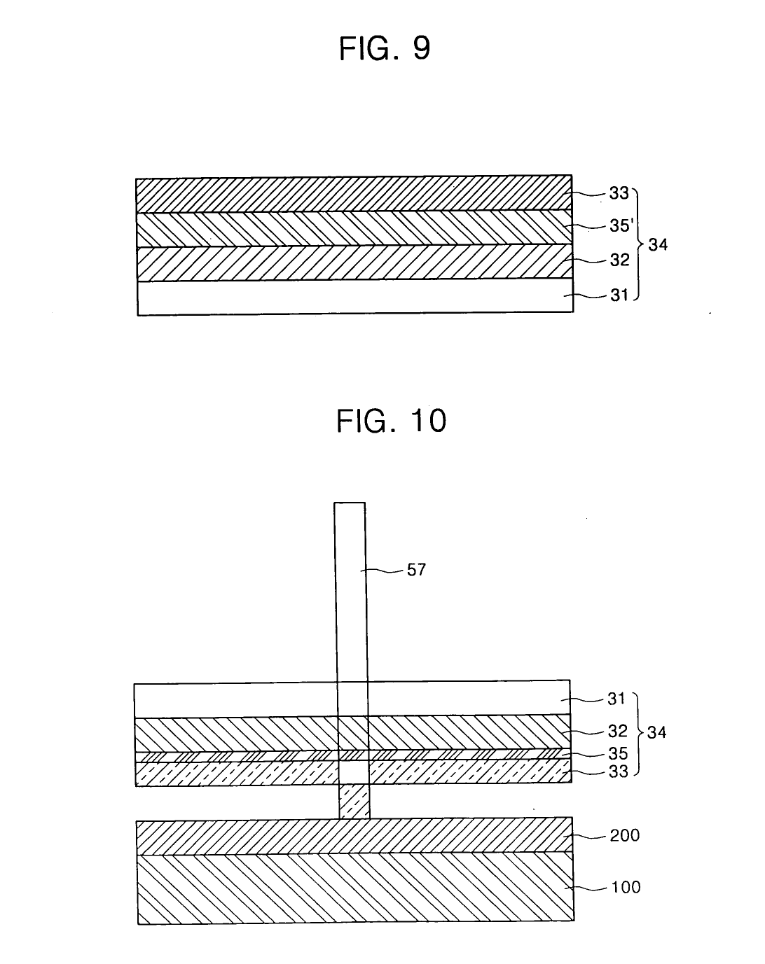

FIG. 9 is a cross sectional view of a donor film for a laser induced thermal imaging method according to a second preferred embodiment of the present invention. Referring to FIG. 9, the second preferred embodiment of the present invention displays the donor film for the laser induced thermal imaging method. The donor film is constructed with a base film 31, a light-to-heat conversion layer 32 and the transfer layer 33. The donor film further comprises a reflection layer 35′ for reflecting an irradiated laser to the light-to-heat conversion layer 32 and preventing gas produced from the light-to-heat conversion layer 32 from infiltrating into the transfer layer 33.

Any materials such as organic material, inorganic material and metal can be used as the reflection layer if they are capable of preventing gas from infiltrating into the transfer layer.

A material having a laser light transmittance of 20% or less is used as the reflection layer, and preferably metal is used as the reflection layer.

A metal selected from the group consisting of aluminum (Al), silver (Ag), chromium (Cr), tin (Sn), nickel (Ni), titanium (Ti), cobalt (Co), zinc (Zn), gold (Au), copper (Cu), tungsten (W), molybdenum (Mo) and lead (Pb) is used as the reflection layer.

The reflection layer is preferably laid to a thickness of 1 μm or less considering gas infiltration blocking force and laser light transmittance of the reflection layer although the thickness of the reflection layer is varied depending on a material used as the reflection layer.

Other constitutional factors adopt the same materials and methods as in the first preferred embodiment of the present invention.

A donor film for the laser induced thermal imaging method disclosed in the present invention is capable of forming fine patterns easily, particularly for an organic electroluminescence display device in which emitting elements are formed of organic material.

A method for forming fine patterns on an organic thin film of an organic electroluminescence display device using a donor film according to the present invention referring to FIG. 10 is described in detail as follows. Although an organic electroluminescence display device is mentioned in the following description as one example to which a donor film of the present invention is applied for convenience of the description, application of the donor film of the present invention is not limited to the organic electroluminescence display device.

FIG. 10 is a drawing describing a method for laser induced thermal imaging using a donor film according to the present invention, wherein a transparent electrode layer 200 is first formed on a transparent substrate 100, and a donor film 34 is prepared by sequentially coating the light-to-heat conversion layer 32, the metal layer 35 and the transfer layer 33 on a base film 31 separately from the transparent electrode layer 200.

The transfer layer 33 is formed by coating an organic thin film forming material on the metal layer 35, wherein additives may be added to the organic thin film forming material to improve various characteristics of the transfer layer 33. For example, a dopant is added to the organic thin film forming material to improve emission efficiency of an emitting layer of the transfer layer. The transfer layer 33 is formed by the foregoing conventional film coating methods including extrusion, gravure coating, spin coating and knife coating.

The transfer layer 33 is laid to one layer using an organic film as described in the above or laid to two or more of layers as occasion demands.

An energy source 37 is irradiated onto the donor film 34 after arranging the donor film 34 on a transparent electrode layer 200 formed on a substrate 100.

The energy source 37 activates the light-to-heat conversion layer 32 by passing through the base film 33 via a laser induced thermal imaging unit and radiates heat by pyrolysis. The irradiated laser beam is retroreflected by the metal layer or the reflection layer 35 so that the energy impressed to the light-to-heat conversion layer 32 is increased.

An emitting layer is transferred to desired patterns and thickness on a pixel region defined by a pixel defining layer on an upper part of the substrate 100 of an organic electroluminescence display device by separating the transfer layer 33 from the donor film 34 as the light-to-heat conversion layer 32 of the donor film is being expanded due to the radiated heat.

An edge open defect caused by stepped surface level generated according to formation of the pixel defining layer is prevented by performing laser induced thermal imaging with at least a certain thickness of the light-to-heat conversion layer 32 as in the present invention, thereby decreasing the radius of the curvature when the light-to-heat conversion layer is expanded.

A laser, a xenon (Xe) lamp, a flash lamp, etc. can be used as an energy source in the present invention. The laser among the energy sources is preferably used to obtain the most superior transfer effect. General lasers including solid, gas, semiconductor and dyes can be used, and a circular or other shaped laser beam can be used.

The laser induced thermal imaging of the transfer material is performed in one-step or multi-step. That is, an organic thin film layer to be transferred is formed to a required thickness by one transfer or several repeated transfers. However, one transfer is preferred in view of process convenience and stability forms the organic thin film layer.

As described in the above, a donor film for the laser induced thermal imaging method according to the present invention increases amount of energy absorbed into the light-to-heat conversion layer by forming a reflection layer or a metal layer between the light-to-heat conversion layer and the transfer layer, prevents damage of the substrate by not transmitting laser beam to the substrate and prevents deterioration of the transfer layer by preventing gas generated from the light-to-heat conversion layer by heat from penetrating into the transfer layer and dissipating heat transferred to the transfer layer.

Furthermore, edge open defect can be reduced with a thin light-to-heat conversion layer, thereby increasing close adherence between the transfer layer and the substrate at a stepped surface level part.

While the invention has been particularly shown and described with reference to preferred embodiments thereof, it will be understood by those skilled in the art that the foregoing and other changes in form and details may be made therein without departing from the spirit and scope of the invention.

1. A donor film for laser induced thermal imaging, comprising:
a base film;
a light-to-heat conversion layer formed on the base film;
a metal layer formed on the light-to-heat conversion layer;
a buffer layer formed on the metal layer; and
a transfer layer formed on the buffer layer and formed of an organic material.

2. The donor film for laser induced thermal imaging according to claim 1, wherein a thickness of the metal layer is 1 μm or less.

3. The donor film for laser induced thermal imaging according to claim 1, wherein the metal layer has a laser beam transmittance of 20% or less.

4. The donor film for laser induced thermal imaging according to claim 1, wherein the light-to-heat conversion layer comprises a material selected from the group consisting of an organic film containing laser light absorbing material, and a metallic compound, said metallic compound selected from the group consisting of metal, metal oxide, metal sulfide and a composite thereof.

5. The donor film for laser induced thermal imaging according to claim 4, wherein the organic film is a mixture of pigment and polymer bonding resin of at least one meta-acrylate oligomer selected from the group consisting of acryl meta-acrylate oligomer, ester meta-acrylate oligomer, epoxy meta-acrylate oligomer and urethane meta-acrylate oligomer.

6. The donor film for laser induced thermal imaging according to claim 4, wherein the metallic compound comprises a metal having an optical density of 0.1 to 4.0 and is selected from the group consisting of aluminum (Al), silver (Ag), chromium (Cr), tin (Sn), nickel (Ni), titanium (Ti), cobalt (Co), zinc (Zn), gold (Au), copper (Cu), tungsten (W), molybdenum (Mo) and lead (Pb).

7. The donor film for laser induced thermal imaging according to claim 5, wherein the organic film has a thickness of 0.1 to 2 μm.

8. The donor film for laser induced thermal imaging according to claim 4, wherein the metallic compound has a thickness of 100 to 5,000 Å.

9. The donor film for laser induced thermal imaging according to claim 1, wherein the donor film further comprises a gas forming layer formed on one of an upper part and a lower part of the light-to-heat conversion layer.

10. The donor film for laser induced thermal imaging according to claim 1, wherein the buffer layer has a thickness of 0.01 to 2 μm, and the buffer layer comprises a material selected from the group consisting of metal oxide, metal sulfide, nonmetal inorganic material, inert polymer and inert small molecule.

11. An organic electroluminescence display device prepared by using the donor film of claim 1.

12. A donor film for laser induced thermal imaging, comprising:
a base film;
a light-to-heat conversion layer formed on the base film;
a transfer layer; and
a reflection layer formed between the light-to-heat conversion layer and the transfer layer to reflect an irradiated laser beam to the light-to-heat conversion layer.

13. The donor film for laser induced thermal imaging according to claim 12, wherein the reflection layer has a laser beam transmittance of 20% or less.

14. The donor film for laser induced thermal imaging according to claim 13, wherein the reflection layer is formed of metal.

15. The donor film for laser induced thermal imaging according to claim 14, wherein the metal is selected from the group consisting of aluminum (Al), silver (Ag), chromium (Cr), tin (Sn), nickel (Ni), titanium (Ti), cobalt (Co), zinc (Zn), gold (Au), copper (Cu), tungsten (W), molybdenum (Mo) and lead (Pb).

16. The donor film for laser induced thermal imaging according to claim 14, wherein a thickness of the reflection layer is 1 μm or less.

17. The donor film for laser induced thermal imaging according to claim 13, wherein the light-to-heat conversion layer comprises a material selected from an organic film containing laser light absorbing material and a metallic compound selected from the group consisting of metal, metal oxide, metal sulfide and a composite thereof.

18. The donor film for laser induced thermal imaging according to claim 17, wherein the organic film is a mixture of pigment and polymer bonding resin of at least one meta-acrylate oligomer selected from the group consisting of acryl meta-acrylate oligomer, ester meta-acrylate oligomer, epoxy meta-acrylate oligomer and urethane meta-acrylate oligomer.

19. The donor film for laser induced thermal imaging according to claim 17, wherein the metal has an optical density of 0.1 to 4.0 and is selected from the group consisting of aluminum (Al), silver (Ag), chromium (Cr), tin (Sn), nickel (Ni), titanium (Ti), cobalt (Co), zinc (Zn), gold (Au), copper (Cu), tungsten (W), molybdenum (Mo) and lead (Pb).

20. The donor film for laser induced thermal imaging according to claim 17, wherein the organic film has a thickness of about 0.1 to about 2 μm.

21. The donor film for laser induced thermal imaging according to claim 17, wherein the metallic compound has a thickness of about 100 to about 5,000 Å.

22. An organic electroluminescence display device prepared by using the donor film of claim 12.
